(19) United States
(12) Patent Application Publication
(10) Pub. No.: US 2004/0004488 A1
(43) Pub. Date: Jan. 8, 2004

(54) Capacitive sensor circuit with good noise rejection

(76) Inventor: Larry K. Baxter, Gloucester, MA (US)

Correspondence Address: Larry K. Baxter, 63 Norwood Heights, Gloucester, MA, 01930, US

(21) Appl. No.: 10/188,598

(22) Filed: Jul. 2, 2002

(51) Int. Cl. G01R 27/26

(52) U.S. Cl. 324/678

(57) ABSTRACT

This invention describes the deficiencies of current art for sensitive impedance sensors, particularly capacitive sensors, and describes several circuits that improve measurement of small value capacitances, especially in the presence of noise. It also shows various circuit architectures optimized for different capacitive sensing tasks.

The circuits also describe a novel method to linearize a conventional charge-transfer capacitive sense circuit and a novel method to eliminate the effect of stray capacitance in charge-transfer capacitive sensors.

### CROSS-REFERENCE TO RELATED APPLICATIONS

Not Applicable

### FEDERALLY SPONSORED RESEARCH

Not Applicable

### SEQUENCE LISTING OR PROGRAM

Not Applicable

### BACKGROUND OF THE INVENTION

This invention shows circuits for measuring small values of capacitance with good rejection of circuit and ambient noise.

1. Field of the Invention

Capacitive sensors have many uses. In practice, a variable to be sensed is converted to a capacitance, this variable capacitance is measured, and its value is observed directly or processed by computer.

The sensed variable can be motion, humidity, proximity, material properties or many others. The capacitance levels may range from a small fraction of a picofarad to many picofarads.

A typical problem requiring measurement of small capacitance in the presence of noise is to detect the proximity of human hand, for example a hand about to be trapped in a closing automobile window or caught in a machine. Systems are available for this purpose that excite a metal plate, perhaps 1″×10″, with an AC voltage of several volts and 1 kHz-1 MHz frequency, and measure the plate's capacitance to ground. As a hand nears, this capacitance increases by a very small value, typically less than one pF. As the environment is often electrically noisy, with nearby fluorescent lamps or radio transmitters, a critical specification is the circuit's noise rejection.

The present invention relates generally to capacitive sensor design, particularly to circuit design for a low-cost capacitive sensor with excellent noise rejection. An alternate embodiment describes a circuit modification to ensure linearity, and a second alternate embodiment shows a modification that improves accuracy by compensating for stray capacitance.

Some patents that describe capacitive sensors in a noisy environment and that could benefit from this invention are U.S. Pat. No. 5,436,613, U.S. Pat. No. 5,525,843, U.S. Pat. No. 5,722,686, U.S. Pat. No. 5,744,968, U.S. Pat. No. 5,802,479, and U.S. Pat. No. 6,158,768.

Two-dimensional finger position sensors or touch panels for computer input often use capacitive sensing. U.S. Pat. No. 4,698,461 shows a capacitively-sensed touch panel that changes the circuit's operation frequency to avoid interfering noise sources; this added circuit complexity would not be needed if the circuit was intrinsically less susceptible to noise.

2. Prior Art

A reference for prior art circuits is Larry K. Baxter, Capacitive Sensors [ IEEE Press, 1997]. As described in this book, three well-known ways to detect a small capacitance are the RC oscillator, the synchronous demodulator, and the charge transfer circuit. These circuits have different strengths and weaknesses, and an understanding of their operation is important for the understanding of the improvements of the present invention.

RC Oscillator, FIG. 1

The prior-art RC oscillator of FIG. 1 is simple. Its frequency is proportional to the reciprocal of capacitance

f=K/RCx

Where K is a constant determined by the threshold voltage of Schmitt trigger 2, and

f is output frequency

R is resistance, here 50K ohms

Variable capacitor 1, Cx, is the capacitance being measured

The RC oscillator detects capacitance as a frequency variation. But it is very susceptible to noise. Interfering noise can be considered as either AC noise, typically confined to a narrow frequency band, illustrated by AM radio transmitters or power line radiation, or impulse noise, typically confined to a narrow time slice, like switch noise, motor brush noise, or semiconductor lamp dimmer transients.

The RC oscillator is susceptible to both noise sources. First, AC noise coupling to the variable capacitance is directly added to the measurement output. This is a serious drawback, as most industrial sites have considerable noise at power frequencies and their harmonics, peaking at 50 or 60 Hz and decreasing towards 100 kHz.

Also, impulse noise acts to increase the frequency by triggering the oscillator prematurely. This behavior is typical of any sense circuit that includes a comparator: an impulse just before the RC voltage reaches the comparator threshold triggers the cycle early, but an impulse just after the threshold is ignored. This imparts a DC offset that is not removed by a following lowpass filter. Other circuits, like FIGS. 2 and 4, do not have this behavior.

A typical RC oscillator for capacitive sensing is described in U.S. Pat. No. 6,307,385.

Charge Transfer Circuit, FIG. 2

The prior-art charge transfer circuit of FIG. 2, described in U.S. Pat. No. 4,345,167, has low power dissipation and better noise rejection than the RC oscillator. In operation, semiconductor switch 5 normally connects capacitor 4, Cx, in parallel with a small stray capacitance 41, to the DC supply voltage 3, say 5V. Cx, charged to 5V, holds a charge Q=CV or 5 pC for a 1 pF Cx. The switch 5 is then momentarily connected to capacitor 6, Cs, for a uS or less, as shown in the timing diagram of FIG. 3. This transfers most of Cx's charge to Cs when SAMPLE is high. SAMPLE is advantageously set to the minimum time t0 that will allow full charge transfer.

As Cs is usually many times larger than Cx, say 100 times larger, Cs′ voltage increases by about 50 mV with each SAMPLE pulse. After switch 5 is cycled perhaps 20 times, the voltage on capacitor 6 is nearly 1V, and this voltage can be easily measured.

The output voltage Vomax is then read externally, coincident with the READ pulse of FIG. 3, then the reset switch 7 is momentarily connected to discharge Cs and the measurement cycle is repeated.

The timing diagram of FIG. 3 shows operation with just four charge transfer pulses. As the number of charge transfer pulses per read-reset operation increases, the noise rejection increases but the response time decreases.

This circuit has an important advantage of sampling speed. It is sensitive to noise only during the very short time interval when switch 5 is connected to capacitor 6, perhaps 20 nS for a fast switch. If t1 is chosen as 10 uS so the excitation frequency is 100 kHz, the circuit is open to noise only 0.2% of the time, and the noise rejection is 500x.

The short sample time possible with a low-cost CMOS switch contributes the noise rejection of a very fast excitation frequency without power-hungry amplifiers, and while using a low excitation frequency with its advantages in power and electromagnetic interference. This fast sample rate at low power, the inherent noise-reducing averaging across many samples, and the voltage gain without amplifiers make this an attractive circuit.

But the charge transfer circuit does not reject AC noise very well. The narrow sampling window improves impulse noise performance considerably compared to the RC oscillator of FIG. 1, but the circuit is influenced by AC noise over a wide bandwidth. Noise frequencies of 60 Hz, for example, couple to Cx and appear directly in the output.

Another drawback of the simple circuit of FIG. 2 is that it is nonlinear, with an exponential transfer function

$${Vo}_{i} := Vs \cdot ( 1 - {ⅇ}^{\frac{- Cx}{Cs} \cdot i} )$$

where i is the number of sample pulses.

A third drawback of this circuit is that stray capacitance 41 from the sensed node of Cx to ground adds to the measured capacitance and hurts accuracy.

Many other charge transfer circuits are described in the literature, such as U.S. Pat. No. 5,451,940, U.S. Pat. No. 5,751,154, and U.S. Pat. No. 6,377,056, but none uses AC excitation so none has the excellent noise rejection of the present invention.

Synchronous Demodulator, FIG. 4

The prior art synchronous demodulator circuit of FIG. 4 shows considerable improvement over FIG. 1. The sensed capacitor 11 is excited with, for example, a square wave generator 8 at 100 kHz. This excitation signal can be produced by a logic gate. This 100 kHz signal also controls switch 15.

A reference capacitor 10 works with measured capacitance 11 as a voltage divider. A unity-gain, low-bias-current operational amplifier 13 buffers the very high capacitive impedance. This amplifier is preferably a FET-input type with a frequency response greater than 10 MHz, such as Analog Device's AD823. Some method of setting the DC level at the amplifier input is needed, such as the high-value resistor 12 or a momentary switch to ground (not shown).

Stray capacitance to ground, as with capacitor 41 of FIG. 2, can add to capacitor 11 and hurt the measurement accuracy. A prior-art solution is shown, where the sense node is shielded and the shield 9 is connected to the output of the unity gain amplifier. The stray node capacitance is converted from capacitance to ground to capacitance to the shield. Stray capacitance is then driven on both sides by the same voltage, no current can flow in it and it disappears from the circuit equation, except by adding to noise. This guard technique can be applied to any of the circuits of this patent.

The variable amplitude square wave at the output of amplifier 13 feeds the synchronous demodulator 14-15, where SPDT switch 15 is a high-speed CMOS switch available from many semiconductor manufacturers, such as Maxim's MAX4053. If the circuit and the switch are integrated on silicon, the switch can have improved performance and lower capacitance. The synchronous demodulator inverts alternate half cycles of the 100 kHz square wave, and the 100 kHz component of the resulting rectified signal is removed by lowpass filter 16. FIG. 5 shows the excitation waveform and the variable-amplitude signal at the output of V13, and the input of the lowpass filter 16, VLPI.

The filtered output measures the capacitance with the nonlinear equation

Vo=Vs·Cx/(Cx+Cr)

This circuit rejects impulse noise better than the RC oscillator but not as well as the charge transfer circuit of FIG. 2. It rejects AC noise better than either; it is sensitive to AC noise only if its frequency is near the 100 kHz carrier, specifically within a frequency band equal to twice the lowpass filter's cutoff frequency centered on 100 kHz. As the LPF bandwidth can be much smaller than 100 kHz, say 1 Hz, the synchronous demodulator can have a very narrow-band response that rejects AC noise. To see how this works, imagine a 60 Hz signal coupled to Cx. It appears at the input of the lowpass filter 16 as a alternate-cycle modulation at a 100 kHz frequency, but the lowpass filter will almost completely remove this high-frequency modulation and hence the 60 Hz component.

The lowpass filter type can be selected to optimize noise rejection, with a simple RC lowpass for AC noise or a median filter for impulse noise.

For best noise rejection the excitation frequency should be very high, say 10 MHz, and the operational amplifier should have ten times this bandwidth for good stability. As the sample time is reduced and the number of sample pulses increases, noise rejection improves directly. A limitation of the synchronous demodulator circuit for low-noise applications is that this high frequency operation requires expensive, power-hungry components and may cause excessive electromagnetic radiation.

### OBJECT OF THE INVENTION

An object of this invention is to improve on the noise rejection of prior art circuits by combining the AC noise rejection of FIG. 4 with the impulse noise rejection of FIG. 2, thereby assuring a noise performance many times the best now available.

A second object is to show how to-apply this improvement to another common capacitive sense application, that of detecting the mutual capacitance of two sense plates.

A third object is to show ways to linearize capacitive sense circuits.

A fourth object is to add a guard electrode to the charge transfer circuit that eliminates or reduces the effect of stray capacitance to ground.

Applications of this invention could be an array of sensors on the skin of a robot to sense proximity, automobile seat sensors to detect the position and size of passengers for airbag deployment, computer-input touch panels, or production line sensors to detect the proximity of metallic objects.

### SUMMARY

Noise rejection is critical for many sensor applications that must work in noisy industrial environments, or in offices with noise-generating fluorescent lamps. This invention describes a simple capacitance measurement circuit with much better noise rejection than current art.

The circuit improvement is to use both the alternate-reversing behavior of the synchronous demodulator with its AC-noise-reducing narrow-band frequency response characteristic and the narrow-pulse-sampling behavior of the charge sampling circuit with its impulse-noise-reducing narrow-window time response. The combination can have a noise performance orders of magnitude better than either one alone.

Also, this invention shows circuit improvements that improve the linearity of a capacitive sensor, useful, too, for other impedance sensors or transfer function sensors.

Also, a way to guard against the effects of stray capacitance to ground with charge transfer circuits is shown.

### FIGURES

FIG. 1 shows prior art, a simple RC oscillator.

FIG. 2 shows prior art, a charge transfer circuit.

FIG. 3 is a timing diagram for FIG. 2.

FIG. 4 shows prior art, a synchronous demodulator.

FIG. 5 is a timing diagram for FIG. 4.

FIG. 6 shows a charge transfer circuit with improved noise performance in accordance with the present invention.

FIG. 7 is a timing diagram for FIG. 6

FIG. 8 shows an improvement over FIG. 6 to measure a ground-referenced capacitor with improved stability and noise.

FIG. 9 is a timing diagram for FIG. 8.

FIG. 10 shows a circuit as in FIG. 8 except configured to measure a capacitor with both terminals available.

FIG. 11 is a timing diagram for FIG. 10.

FIG. 12 shows a method of correcting the linearity of FIGS. 2, 4, 6, 8, and 10.

FIG. 13 shows an alternate circuit for a charge transfer demodulator with the noise advantages of FIG. 6 and a linear curve of output voltage vs. capacitance or a linear curve of output voltage vs. the reciprocal of capacitance.

FIG. 14 shows the circuit of FIG. 8 with improved linearity and a way to guard stray capacitance.

### DETAILED DESCRIPTION

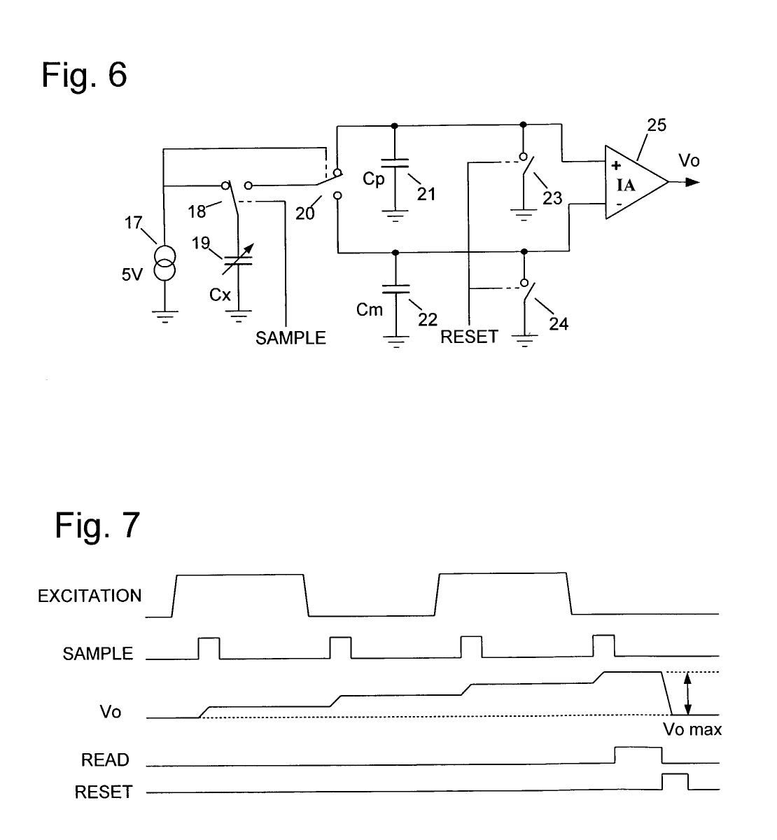

Improved Charge Transfer Circuit, FIG. 6

FIG. 6 and the timing diagram of FIG. 7 show a circuit with improved noise rejection, an embodiment of the current invention. First, a bipolar ±5V square wave 17 is connected through switch 18 to charge measured capacitor 19, Cx, to +5V. Switch 18 then is momentarily connected to switch 20 and capacitor 21 for about 20 nS during SAMPLE time to dump Cx′ charge into capacitor 21. The cycle repeats for each reversal of the excitation squarewave; on negative excursions of square wave 17, switch 18 charges capacitor 19 to −5V and dumps this charge into capacitor 22.

The sample time, as shown in FIG. 7, should be delayed from the excitation so that Cx is fully charged before sampling.

Although only four cycles are shown, generally this sequence repeats at about 100 kHz for a large number of cycles, say 200, until Cp is charged to about +1V and Cm is charged to −1V. Instrumentation amplifier 25, similar to Texas Instruments' INA311, outputs VCp−VCm and the capacitors 23, 24 are discharged by the RESET pulse, ready to begin a new measurement cycle.

Cp and Cm should be equal value for best noise rejection. If Cp=Cm=Cs, the output equation is

$${Vo}_{i} := Vs \cdot ( 1 - {ⅇ}^{\frac{- Cx}{Cs} \cdot i} )$$

where i is the number of sample pulses.

This circuit improves on the charge transfer circuit, as it responds to noise as does the sync demodulator, that is, only to noise very close to the 100 kHz excitation frequency. And it retains the noise rejection of the simple charge transfer circuit, as its sample switch is only open to noise for 20 nS every 10 uS. So its noise rejection can be a factor of 250 better than the synchronous demodulator, and also a large factor improvement on the simple charge transfer circuit. Both circuit noise and ambient noise are rejected.

For the charge transfer circuits of FIGS. 2, 6, 8, 10, and 12, the reset switch may be replaced with a high-value resistor Rr, chosen so the time constant Cs·Rr is larger than the excitation period.

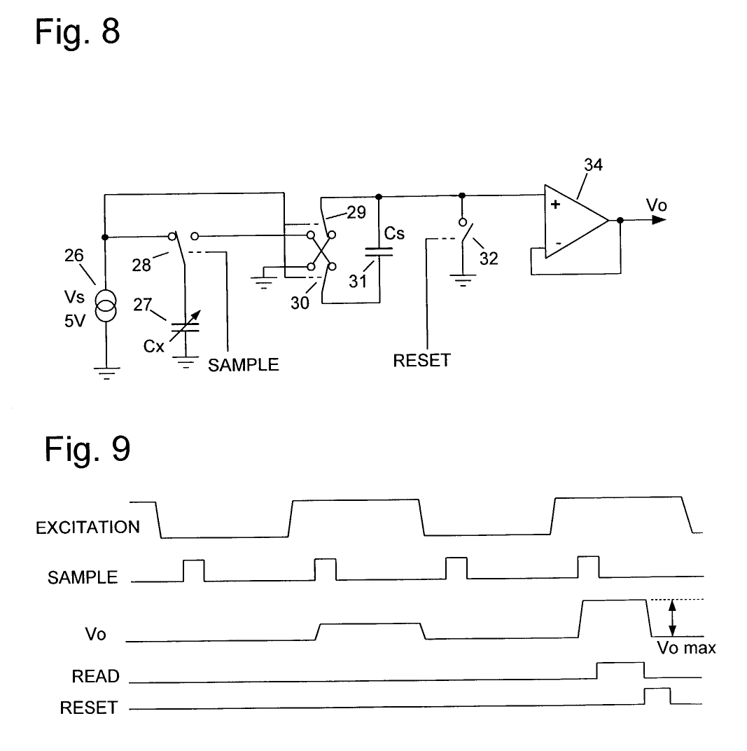

Further Improved Charge Transfer Circuit, FIG. 8

A problem with FIG. 6 is that the two channels VCp and VCm must be carefully balanced for good performance. If the capacitors Cp and Cm are not identical, noise rejection suffers. This problem is handled with the circuit of FIG. 8, with timing diagram FIG. 9, where only one storage capacitor Cs is used. Capacitor Cs, 31, is connected through sample switch 28 to capacitor 27, Cx, through a reversing switch 29, 30. Cx is charged to alternately positive and negative voltage by 100 kHz excitation 26, but capacitor 31 is charged just positively.

Capacitor 31 is buffered with a high impedance amplifier 34. Its output Vo measures Cx at READ time; it can feed a sample-and-hold circuit or a sampling analog-to-digital converter responsive to the READ pulse. After Vo is read, storage capacitor 31 is reset by switch 32 to initialize the circuit for the next measurement.

The output equation of FIG. 8 is the same as the output equation of FIG. 6.

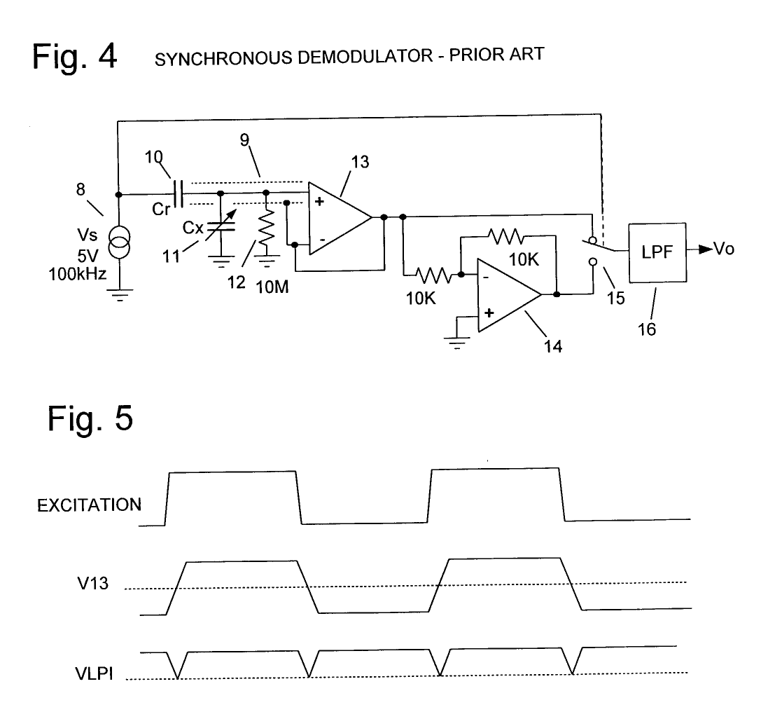

Alternate schemes are possible to handle sampling and demodulation, the reversing switch is not needed. Any switching scheme needs to sample the charge of Cx with a short time window and also needs to provide a method to collect the alternating charge packets and sum them to a DC level. For instance, another possible implementation is, with appropriate logic changes, to combine the functions of switches 28, 29, 30 into two switches. Or the synchronous demodulator of FIG. 4 may be used, with a short-time-window sample and hold following the input amplifier, timed to sample soon after the excitation transition.

The circuit of FIG. 8 has further advantages over the simple charge transfer circuit of FIG. 2 and also over FIG. 6. Semiconductor switches inject a small charge at their terminals with every transition, on the order of a few pC. This injected charge may be more than the measured charge and may not be stable, changing with temperature and DC voltage level. This problem is handled by FIG. 8, however, as the injected charge alternates for each pulse, and an output lowpass filter averages the variations to zero.

FIG. 8 is a preferred embodiment for low noise capacitive sensors if linearity and stray capacitance rejection are not needed.

In summary, the simple charge transfer circuit of FIG. 2 improves upon the synchronous demodulator circuit of FIG. 3 by use of a very narrow sample window that rejects noise, and the current invention as shown in FIG. 6 and FIG. 8 improves on the simple charge transfer circuit of FIG. 2 by reversing the excitation for alternating samples. This AC excitation blocks low-frequency noise, has a narrow bandpass response that further rejects noise, and rejects several circuit contributions to noise and instability such as charge injection and amplifier offset voltage.

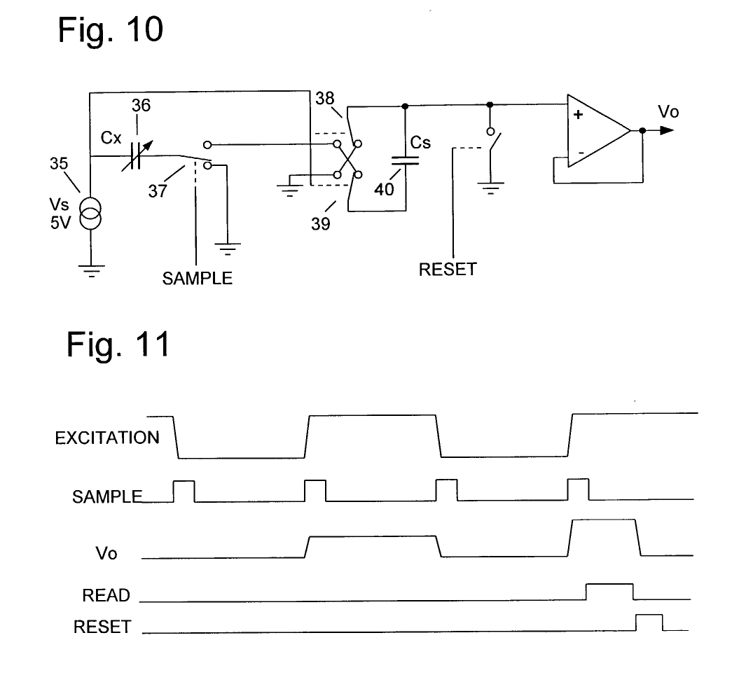

Floating Capacitor Implementation, FIG. 10

The circuits described so far have a measured capacitor with one plate connected to ground. Some improvement in performance is possible if neither plate of the capacitor is grounded; one benefit is that stray capacitance to ground does not affect the measurement. Simple circuit modifications handle this case.

In FIG. 10, the right side of floating capacitor 36 is normally connected to ground through switch 37, which should be a break-before-make type. The SAMPLE pulse briefly energizes switch 37 and connects capacitor 36 through switch 37 to the storage capacitor 39 as shown in the timing diagram of FIG. 11. To capture all of capacitor 36's charge, switch 37 should be disconnected from ground just before the transition of the excitation voltage 35 and connected to the reversing switches 38 and 39 just after the transition. Capacitor 40, Cs, then captures the charge packet at the risetime.

The break-before-make switch can, of course, be replaced by a switch with an inhibit input to guarantee a long make-before-break interval for more reliable timing, or two switches with correctly phased controls.

The excitation frequency, shown as 100 kHz, can be almost any convenient value from 1 kHz to several MHz. The waveform can be square, rectangular, or narrow pulses of alternating polarity. Its DC level is unimportant. For one-plate-grounded capacitors, sinewave excitation with sampling at the peaks works well. Floating capacitors need a fast-rise-time excitation waveform like a squarewave, sampled at the transitions.

Linearity

A problem of all the charge transfer circuits shown is linearity. The output voltage is fairly linear with capacitance for low voltage levels, but as the output approaches the excitation voltage, the slope of the response trails off in classic exponential fashion. This can be handled by replacing the storage capacitor Cs with an operational amplifier, but the main advantage of the charge transfer circuit is lost, as this amplifier would need to have a very high frequency response for good charge transfer efficiency. If the amplifier frequency response is not at least 10 times higher than the excitation frequency the output will be low and unstable.

Linearity Correction, FIG. 12

In applications where linearity is desired, a better solution is shown in FIG. 12. This circuit is identical to FIG. 2, except the output voltage from 49 feeds back to the negative terminal of excitation 45, so as the output increases the excitation voltage also increases. This could be done with a floating battery 45 as shown. Alternately and preferably the battery could be replaced by a capacitor with a value high enough to store charge with low droop, with its voltage set to Vs during the reset cycle. FIG. 12's equation is

$${Vo}_{i} := j \cdot ( \frac{Cx}{Cs} \cdot Vs )$$

with i the number of sampling pulses in the measurement interval. The output voltage increases linearly with sampling, saturating at 2*Vs.

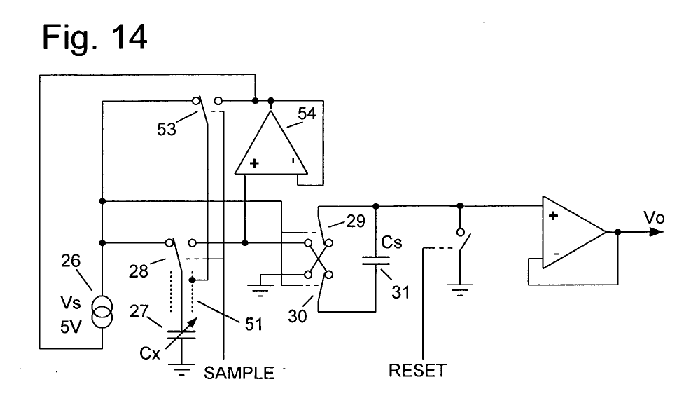

The linearizing technique shown in FIG. 12, feeding the output voltage back to the excitation voltage, can be applied to any of the charge transfer circuits, that is, FIGS. 2, 6, 8, and 10. For FIGS. 6, 8, and 10, capacitor Cs′ voltage must be buffered and fed back to control the amplitude of the AC excitation as will be shown in the discussion of FIG. 14.

Guarding Stray Capacitance, FIG. 12

Stray capacitance to ground in any of the charge transfer circuits, shown as capacitor 41 in FIG. 2, can be guarded with a shield connected as shown in FIG. 12. A conducting shield shown as a dotted line surrounds the sense node of capacitor 46, Cx. The capacitance to ground is then replaced by capacitance to the shield. Then the shield is connected with break-before-make SPDT CMOS switch 47 alternately to the drive voltage and to the output buffer. As Cx is discharged by the sample pulse from Vs to Vo (the voltage on the storage capacitor Cs), the guard shield is driven to follow this voltage. With an identical voltage transient on both of its terminals, no current flows in the stray capacitance. This guarding technique is a preferred embodiment of the current invention in applications where stray capacitance is a problem.

FIG. 14 illustrates a novel extension of this type of guard to a charge transfer circuit with AC excitation.

Many other circuits can be imagined to accomplish this result.

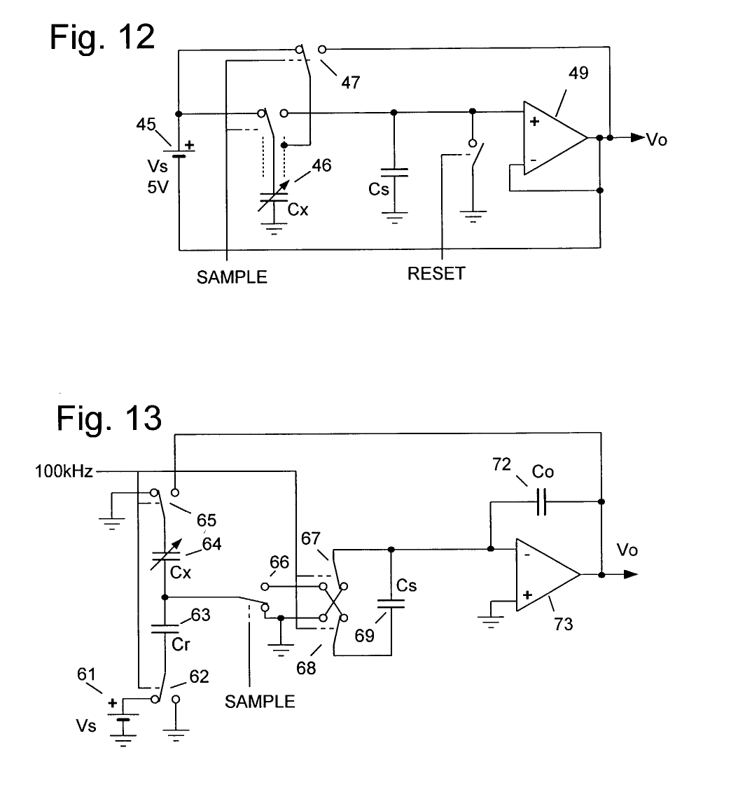

Feedback Demodulation, FIG. 13

Another charge transfer circuit that retains the advantages of a short sampling window and AC excitation while providing a linear transfer function is shown in FIG. 13. This circuit is a preferred embodiment where the capacitor to be measured has both plates floating and where a reference capacitor is available, preferably with characteristics that closely track the measured capacitor.

FIG. 13 is also preferred if the output signal must be linear with the reciprocal of Cx, rather than linear with Cx as in FIG. 12.

In FIG. 13 a reference capacitor 63 is connected in a bridge circuit with the measured capacitor 64, Cx, with opposite excitation polarity.

The amplifier gain is very high for this circuit, say 100,000, not the 1× gain of previous circuits. Its steady-state equation, assuming high amplifier gain, is

$$Vo := Vs \cdot \frac{Cr}{Cx}$$

The output of the circuit as shown is linear with the reciprocal of Cx, useful for measuring changes of capacitor plate spacing. The position of the variable capacitor can be reversed with Cr if a linear-with-Cx output is needed.

Operation

With each cycle, the sampling switch 66 dumps the combined charge of capacitor 63 and 64 through reversing switch 67, 68 into storage capacitor 69. As the excitation driving capacitor 63 and capacitor 64 is opposite in phase, this charge will be nulled if the output voltage is equal to Vs and if capacitors 63 and 64 are equal.

The timing diagram is similar to FIG. 11, with break-before-make switch 66 overlapping the excitation transient.

Each cycle the charge collected by capacitor 69 is dumped through switch 70 into capacitor 72, so if the bridge is out of balance Vo slews to rebalance it. Operational amplifier 73 should have a frequency response several times higher than the excitation frequency so that capacitor 72 can collect most of capacitor 69's charge. After startup, in a few tens or hundreds of cycles, the negative feedback drives the output voltage to a value that nulls the charge dumped into capacitor 69 and the circuit's equation (above) is satisfied.

This feedback circuit has a response time determined by capacitors 69 and 72, so these values should be low for fast response or high to filter noise. Of course, correct negative feedback polarity is needed.

The features of FIG. 13 can also be altered to suit the application. The 5V excitation of FIG. 8 is here replaced with a voltage supply 61 and a switch 62 to better track the characteristics of switch 65, but logic gate excitation is also an option. The reversing switch 67, 68 is a convenient way to demodulate the alternating charge packets, but other methods such as the synchronous demodulator of FIG. 3 are possible.

Guarding and Linearizing the Grounded-Capacitor Circuit, FIG. 14

FIG. 14 adds two parts to FIG. 8 to improve its linearity and to guard stray capacitance to ground. Its timing diagram is identical to FIG. 9.

Linearity is simply improved by buffering the high-impedance measured capacitor 27 with operational amplifier 54 and feeding this voltage back to the excitation 26. As storage capacitor 31 receives charge pulses and assumes an increasing positive voltage, the reversing switch 29, 30 presents amplifier 54 with an alternating voltage of increasing amplitude. Amplifier 54's output adds to the excitation voltage so that each charge pulse is the same value, instead of exponentially decaying as capacitor 31 charges.

The amplifer should be fast enough to respond in a fraction of a cycle of the excitation voltage and have high imput impedance. Analog Device's AD823 is a good choice.

Guarding is handled by adding switch 53. This switch operates in parallel with the normal sampling switch 28, injecting an equal and opposite charge into any parasitic capacitance between the sensed node and the guard shield 51. The sample pulse simultaneously drives the shield surrounding the sensitive node of Cx to a voltage that matches storage capacitor 27's voltage.

Preferred Embodiments

FIG. 8 is preferred for low-noise applications with a measured capacitor having one terminal grounded. If good linearity is needed, feedback to the excitation voltage as taught in FIG. 14 is added. If guarding of stray capacitance to ground is needed, the guard circuit of FIG. 14 is added.

FIG. 10 is used for a measured capacitor has both terminals available, and its linearity can optionally be improved with the feedback to the excitation voltage as taught in FIG. 12.

FIG. 13 is preferred for a measured capacitor with both terminals available, with an output that is linear with capacitance or linear with the reciprocal of capacitance.

Conclusion and Scope

Several important advances for capacitive sensing circuits can be seen in this invention. The characteristics of synchronous demodulators and charge transfer circuits have been advantageously combined in a way to greatly increase the noise resistance, and added circuits show how to improve linearity and reject stray capacitance.

The descriptions show several circuits, but the scope of the invention is not limited to these particular implementations. For example, the linearity improvement illustrated in FIG. 14 could be applied to FIG. 6, or the synchronous demodulator of FIG. 4 could replace the reversing switch of FIG. 8.

The scope of the invention should not be limited by the particular cases illustrated above, but rather determined by the appended claims.

I claim:

1. A circuit to measure small values of a capacitive impedance, comprising
a. an excitation voltage that generates an alternating current waveform in a measured capacitor,
b. sampling means arranged to measure alternating positive and negative charge packets from said measured capacitor during a predetermined time interval shorter than the period of said excitation voltage,
c. demodulation means to demodulate the output of said sampling means to a signal representative of the value of said measured capacitor,
whereby noise will be rejected by inverting and averaging alternate noise samples and by sampling with a narrow time window.

2. The circuit of claim 1 wherein the charge stored in said measured capacitance is transferred to two sampling capacitors, with the first sampling capacitor assuming a voltage representing said charge during positive excitation and the second sampling capacitor assuming a voltage representing said charge during negative excitation.

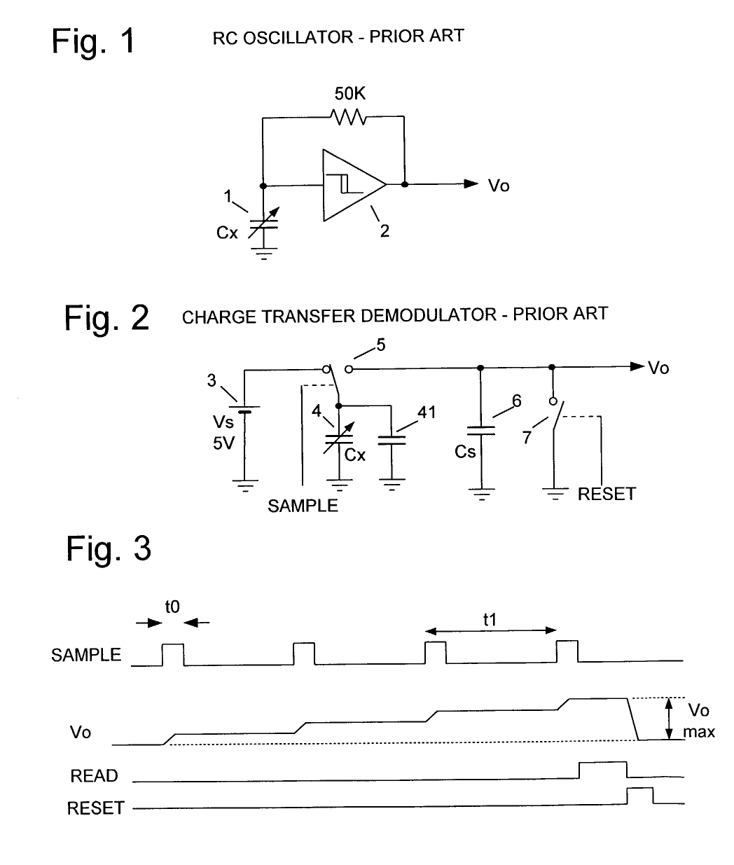

3. The circuit of FIG. 1 wherein said sampling circuit is preceeded with high impedance buffer means.

4. The circuit of claim 1 wherein said demodulator is a reversing switch connected to said sampling capacitor.

5. A circuit to measure small values of a capacitive impedance, comprising
a. a single-pole double-throw switch arrangement to alternately charge a measured capacitor to an excitation voltage and discharge said measured capacitor to a sampling capacitor,
b. a high-input-impedance unity-gain buffer amplifier to convey the sampling capacitor's accumulated voltage to an output port,
c. a feedback mechanism so that the voltage at said output port is added to said excitation voltage to linearize the equation of output voltage vs. capacitance,
whereby the output voltage will have a linear relationship with the measured capacitance.

6. The circuit of claim 5 wherein the excitation is an alternating current.

7. A nulling circuit to linearly measure small values of capacitive impedance, comprising
a. a reference capacitor in series connection with a measured capacitor,
b. a fixed alternating-current excitation voltage source connected to said reference capacitor,
c. a variable-amplitude alternating-current excitation voltage source connected to said measured capacitor with its waveform in phase opposition to said fixed alternating-current excitation voltage,
d. amplification and demodulation means with a gain substantially greater than one, an input connected to the junction of said reference and measured capacitors, and an output with a direct-current level responsive to the difference of said reference capacitor's charge and said measured capacitor's charge,
whereby the output of said amplifier and demodulator means assumes a value to null the difference of said reference capacitor's charge and said measured capacitor's charge and
whereby said output is related to the ratio of the measured and reference capacitors.

8. A nulling circuit according to claim 7, wherein said demodulation means preceeds said amplification means and is accomplished with a reversing switch.

9. A nulling circuit according to claim 7, where said amplifier means includes a frequency-shaping network such as an integrator whereby a suitable output response speed may be chosen.

10. A circuit to measure small values of capacitive impedance while ignoring stray capacitance to ground, including
a. a measured capacitor connected to an additional undesired stray capacitance,
b. sampling switch means to charge said measured capacitor and discharge it into a storage capacitor,
c. guarding switch means that intercept said stray capacitance with an electrostatic shield and drive said electrtostatic shield with a voltage representing the voltage on said measured capacitor,
whereby the effect of said stray capacitance is removed from the measurement.
